(19) United States
(12) Patent Application Publication
(10) Pub. No.: US 2023/0265564 A1
(43) Pub. Date: Aug. 24, 2023

(54) PROTECTIVE LAYER AGAINST ENVIRONMENTAL INFLUENCES (ENVIRONMENTAL BARRIER LAYER) FOR Tl-AL MATERIAL

(71) Applicant: OERLIKON SURFACE SOLUTIONS AG, PFÄFFIKON, Pfäffikon (CH)

(72) Inventors: Beno Widrig, Bad Ragaz (CH); Oliver Jarry, Koln (DE); Bernhard Kohlhauser, Wien (AT); Jürgen Ramm, Maienfeld (CH)

(21) Appl. No.: 18/003,759

(22) PCT Filed: Jun. 29, 2021
(86) PCT No.: PCT/EP2021/067866

§ 371 Date: Dec. 29, 2022

(30) Foreign Application Priority Data
Jul. 1, 2020 (EP) 20405020.7

(51) Int. Cl. C23C 28/00

(52) U.S. Cl. CPC C23C 28/325; C23C 28/3215; C23C 28/345

(57) ABSTRACT

A surface coating for protecting substrates with Ti—Al material, preferably comprising one or more of the materials from table 1, wherein the coating comprises a layer sequence with at least one layer which forms a diffusion barrier for Ti, preferably according to one or more of the layer sequences specified in table 1 in rows, and wherein the coating comprises an oxidation barrier which is in particular adjusted to the diffusion barrier and preferably adjusted according to table 2, and in particular wherein the surface coating comprises a thermal barrier which is preferably adjusted to the oxidation barrier according to table 3.

### FIELD OF THE INVENTION

The present invention relates to a surface coating for protecting Ti—Al-based materials with high mechanical strength—as can be achieved by introducing intermetallic Ti—Al phases into these materials—against corrosive, particularly oxidative wear. The invention also relates to a layer system which can be used as a thermal barrier layer. The invention also relates to a method for producing the surface coating. In the context of the following description, different barriers are mentioned. In each case, the following shall be meant:

Environmental Barrier Coating:

Protective layer comprising one or, in most cases, a plurality of individual layers in order to protect a substrate surface from damaging influences caused by the environment, for example protection against oxidation, corrosion, evaporation, volatilization, erosion.

Diffusion Barrier:

The diffusion barrier has the task of preventing the diffusion of elements between the substrate and a further layer, for example an oxidation barrier layer, or only allowing limited diffusion. As a rule, the diffusion barrier is realized by a diffusion barrier layer.

Oxidation Barrier:

The oxidation barrier according to the present description prevents or drastically reduces the diffusion of oxygen to the diffusion barrier layer or to the interface between the diffusion barrier layer and the substrate surface. As a rule, the oxidation barrier is realized by an oxidation barrier layer.

Thermal Barrier:

The thermal barrier has the task of protecting the substrate material from excessively high temperatures and thus making it usable for temperature ranges that are above its operating temperature with regard to mechanical strength. As a layer (thermal barrier layer), it is designed with a sufficiently large thickness and/or sufficiently small thermal conductivity in such a way that a desired temperature drop is achieved via its thickness.

### BACKGROUND OF THE INVENTION

Ti—Al based materials are preferred and desirable materials for components in aircraft turbines because of their low density and high strength. Therefore, Ti—Al-based materials are currently being tested for their suitability to replace Ni-based superalloys in particular in the aircraft sector [B. P. Bewlay et al., Materials at High Temperatures 33 (2016) 549; N. P. Padture, Nature Material 15 (2016) 804]. Moreover, these materials are also used in other fields, such as in applications in high-performance automotive engineering [T. Tetsui and Y. Miura, Mitsubishi Heavy Industries, Ltd., Technical Review 39 (2002) 1] and in nuclear industry [H. Zhu et al., The Journal of The Minerals, Metals & Materials Society 64 (2012) 1418]. However, these materials have the disadvantage that they are not resistant to oxidation at high temperatures and are subject to diffusion processes which deteriorate their mechanical properties.

The object of the present invention is to provide a surface coating for a Ti—Al substrate which is resistant to oxidation at high temperatures and, in particular, does not deteriorate the mechanical properties.

The object of the invention is to provide a method for producing a surface coating for a Ti—Al substrate, with the surface coating being resistant to oxidation at high temperatures and in particular not deteriorating the mechanical properties.

High temperatures can be understood to mean in particular temperatures of over approximately 900° C.

In the context of turbine applications, in particular Ti—Al-based materials are examined which contain the intermetallic phases γ-TiAl and α2-Ti3Al and which can contain additional dopants with other elements, as are described, for example, by N. R. Muktinutalapati, Materials for Gas Turbines—An Overview, Advances in Gas Turbine Technology, Dr. Ernesto Benini (Ed.), (2011) (ISBN: 978-953-307-611-9) in table 13 on page 308. As already mentioned, the surfaces of these materials must be protected against oxidation and the diffusion processes which occur at high temperatures both in the substrate material and in the region between substrate material and oxidation protection layer must be prevented or controlled to a desired extent. In general, a protective coating comprising a diffusion barrier layer and an oxidation barrier layer (FIG. 1) is therefore sought. In addition, it is examined whether the application of such materials can be extended to even higher operating temperatures by an additional thermal barrier layer applied onto the oxidation barrier layer. As it is known, for the Ni-based superalloys, such a thermal barrier layer is realized by applying, as a first layer on the superalloy, a so-called MCrAlY layer as an interface (intermediate layer), which, however, has a similar fcc (face-centred cubic) structure as the superalloy, but has a slightly higher Al content than the superalloy substrate, and which forms a dense thin aluminum oxide layer, the so-called oxide scaling, on its surface, when heated in an ambient atmosphere above approximately 1000° C. This MCrAlY layer can be combined with a thick (200 μm to 1000 μm) and also porous YSZ (yttria-stabilized zirconia) layer, over which a temperature drop of up to 150° C. can be achieved, thus enabling a higher operating temperature for the superalloy substrates. This approach would of course also be advantageous for the Ti—Al-based substrates, but is difficult to realize, since heating to the necessary 1000° C. would reduce the strength of the substrate material before a protective layer can be formed.

An important condition for increasing the oxidation resistance of the Ti—Al material with a surface coating is the stability of the interface between the coating and the Ti—Al substrate material. Some reasons for this are discussed below. Even during the coating, the increased energy input at the substrate surface can lead to diffusion processes in the near-surface region of the substrates to be coated and in the first layers of the coating. Such diffusion processes depend both on the type of metal vapor used for coating and on the process gases added to the coating process. For example, nitrogen diffusion into the substrate occurs if, for example, layers of TiN or TiAlN are to be applied, i.e. the layer synthesis takes place by means of a nitrogen plasma. This nitrogen diffusion leads to a weakening of the mechanical properties in the near-surface region of the substrate to be coated. The weakening effect is even more drastic, if the Ti—Al substrate surface comes into contact with oxygen during coating. The result is the formation of Ti—O compounds which have poor mechanical properties. Simultaneously with such oxidation processes, there are accelerated diffusion processes that promote instability of the interface, which usually manifests itself in void formation.

As is the case with the superalloys, there is also a desire for the Ti—Al materials to extend their range of use towards higher temperatures. This can be done by applying a thermal barrier layer via which a temperature drop can be realized. In this case, the thermal barrier layer can be an additional layer system which is applied to the layer system of FIG. 1 (shown in FIG. 2). However, there is a simplified approach, namely by adding a thermal barrier layer to the layers described for the environmental barrier coating (EBC) in FIG. 1, for example by making the oxidation barrier significantly thicker (shown in FIG. 3). Layer materials with which a particularly large temperature drop can be realized, i.e. materials with low thermal conductivity but with good mechanical stability at high temperatures, are particularly suitable for a thermal barrier layer. In the case of the Ti—Al materials to be protected here, temperatures above 900° C. can already be regarded as high temperatures, because these would allow a significant expansion of the area of application of these Ti—Al materials (N. R. Muktinutalapati, Materials for Gas Turbines—An Overview, Advances in Gas Turbine Technology, Dr. Ernesto Benini (Ed.), (2011) (ISBN: 978-953-307-611-9) in table 13 on page 308). In other words, the thermal barrier layer does not necessarily have to be based on a YSZ material that is thermally stable up to about 2000° C., but it could also be a material that has thermal stability up to about 1500° C. or even below that temperature. In addition to the desirable low thermal conductivity of such materials, it is particularly important that the coating process can produce a layer morphology that is characterized by high porosity but is still mechanically stable.

### SUMMARY OF THE INVENTION

A first solution to this problem is a layer system according to FIG. 1, whose interface between layer and substrate either prevents diffusion or is stabilized by (limited) diffusion processes, i.e. it forms no voids (or only an insignificant number).

In addition, the layer system according to the invention according to FIG. 1 has a stable oxidation barrier on its surface or it forms such a stable oxidation barrier during operation so that no oxygen can reach the substrate/layer interface.

These two requirements are necessary conditions for a layer system that guarantees the stability of the surface of Ti—Al substrate materials for a predetermined temperature range. This temperature range is determined on the one hand by the specific application and on the other hand by the mechanical strength of the Ti—Al base material, which depends, inter alia, on the chemical composition, crystal structure and crystallite size.

A further aspect of the layer system according to the invention is that, in the variants according to the invention, the environmental barrier coating of FIG. 1, as shown in FIG. 2, is extended by a thermal barrier layer.

### DESCRIPTION OF THE FIGURES

FIG. 1 schematically shows a layer system according to the invention of an environmental barrier coating for Ti—Al material. The figure includes the Ti—Al substrate material 101, which can be, for example, a material described in N. R. Muktinutalapati, Materials for Gas Turbines—An Overview, Advances in Gas Turbine Technology, Dr. Ernesto Benini (Ed.), (2011) (ISBN: 978-953-307-611-9) in table 13 on page 308. But it can also show modifications in chemical composition. Within the scope of the invention, the first layer 102 is deposited on this substrate material, which layer, with regard to its function, is a diffusion barrier for the temperature range of the specific use of the material. At the same time, this diffusion barrier guarantees the adhesion of the entire layer system to the substrate material. The layer has the task of preventing diffusion between the substrate and the following layer or only allowing limited diffusion, which leads to an improvement in adhesion to the substrate, but is limited by the amount of material available (thin layer). A thin metallic layer 121 can advantageously be used to improve adhesion on the different substrate materials and for the different areas of application of the layer systems. In addition, it may be helpful to create a gradient 122 in the chemical composition of the metal-silicon layer before coating the metal-silicon layer composition desired in terms of its chemical composition as the actual diffusion barrier (102).

The second layer of the layer system 103 prevents diffusion of the oxygen (oxidation barrier) to the diffusion barrier or to the interface between diffusion barrier and substrate surface. Depending on the layer material, it may be advantageous for a protective oxide scaling 123 to be produced on the Me-Si diffusion barrier before the oxidation barrier is deposited in an oxygen environment, so that the diffusion of activated oxygen from the oxygen plasma, which is required for the synthesis of the oxidic oxidation barrier, is prevented.

Essential features for an effective environmental barrier coating are the prevention of Ti diffusion to the surface of the layer system after the annealing process in the atmosphere and the evidence of good adhesion between the layer system and the substrate after annealing in the ambient atmosphere.

### FIGURES

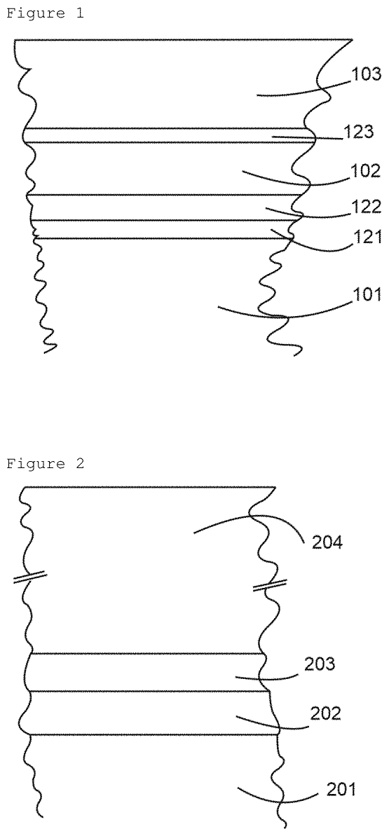

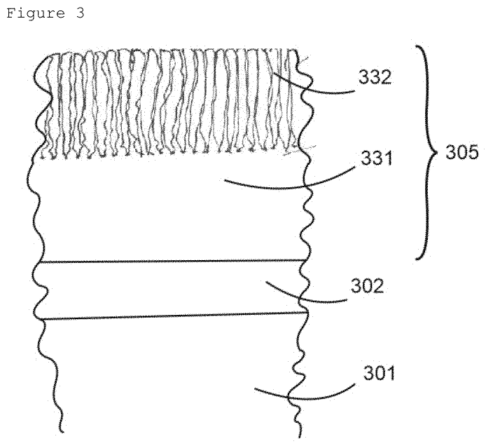

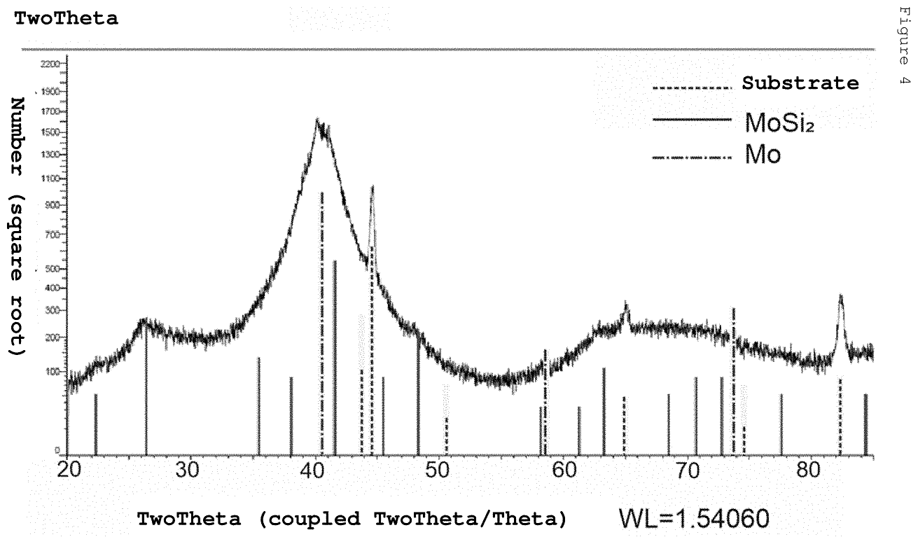

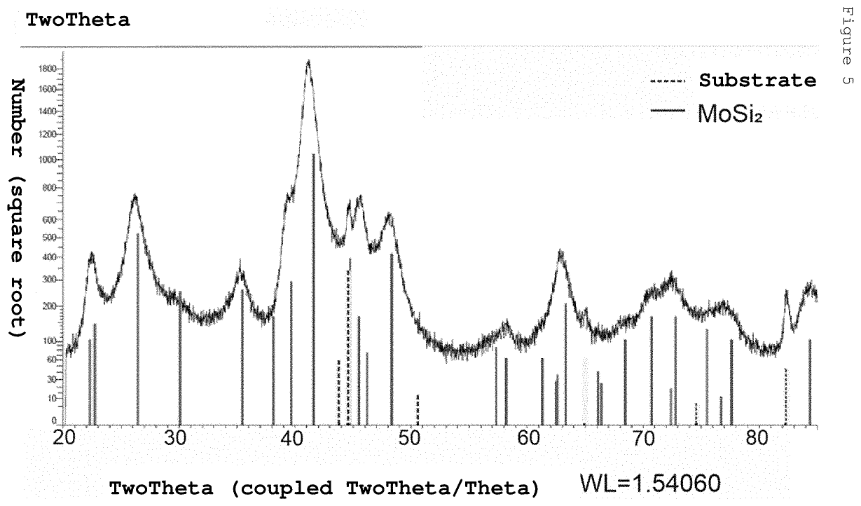

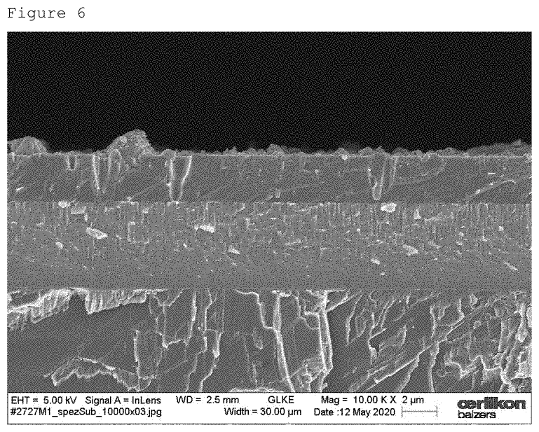

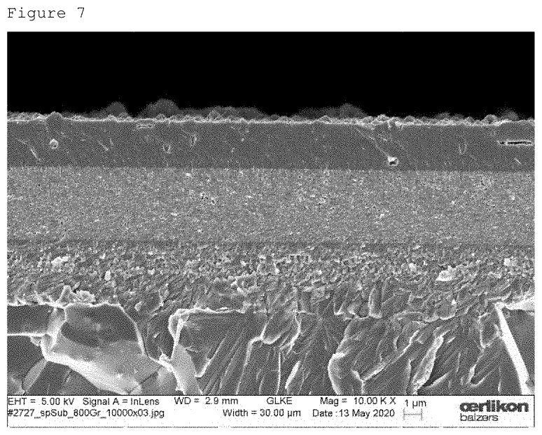

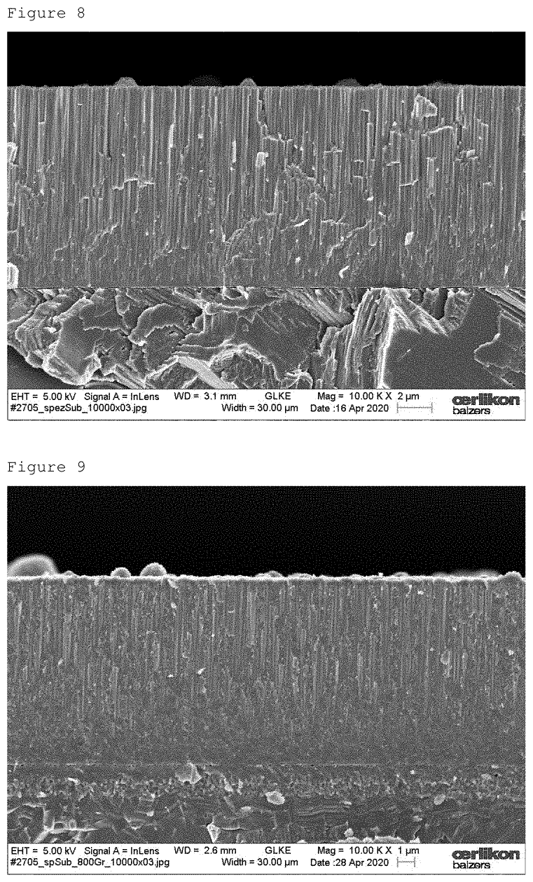

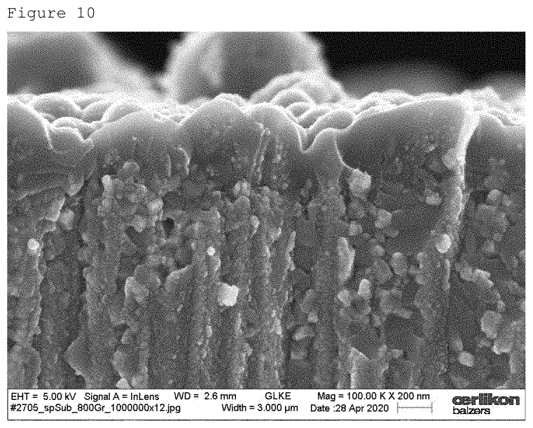

FIG. 1

Layer system according to the invention for an EBC on a Ti—Al substrate, consisting of substrate 101, diffusion barrier 102 and oxidation barrier 103.

In FIG. 1, the following reference numbers mean:
101 Ti—Al-based substrate to be protected against oxidation.
102 Diffusion barrier layer which is applied as an intermediate layer (interface) between Ti—Al-based substrate and the oxidation barrier layer.
121 Metallic adhesive layer
122 Gradient layer in the metal-silicon layer material
123 Oxide scaling
103 Oxidation barrier layer that seals the layer system on its surface towards the environment against oxidative processes.

FIG. 2

Layer system according to the invention for an EBC on a Ti—Al substrate, consisting of substrate 201, diffusion barrier 202, oxidation barrier 203 and a further thermal barrier layer 204.

That is, FIG. 2 shows the extension of the oxidation barrier layer 203 by a further layer 204, which has the function of a thermal barrier layer. In general, such a thermal barrier layer is thermally stable in the predetermined temperature range and preferably has low heat conduction, which is given by the layer material—for example by an oxide—or is achieved by an increased porosity of the layer.

In FIG. 2, the following reference numbers mean:
201 Ti—Al-based substrate to be protected against oxidation.
202 Diffusion barrier layer which is applied as an intermediate layer (interface) between Ti—Al-based substrate and the oxidation barrier layer
203 Oxidation barrier layer that seals the layer system on its surface towards the environment against oxidative processes
204 Thermal barrier layer

FIG. 3:

Layer system according to the invention for an EBC on a Ti—Al substrate, consisting of substrate 301, diffusion barrier 302, oxidation barrier 305 from 331 and 332, which has been expanded to a greater layer thickness and comprises the layer morphology in 332 which becomes more porous, as the layer thickness increases.

Accordingly, a further layer system is shown in FIG. 3, which, compared to the layer system in FIG. 2, shows a simplified layer structure. In this layer system, the oxidation barrier layer 203 and the thermal barrier layer 204 from FIG. 2 are combined in one layer 305 that fulfils both functions. This can be achieved by a gradient in the layer morphology, for example by making the layer 305 denser near the interface 331 to achieve good adhesion. But then, as the layer thickness increases, the layer 305 gradually and/or continuously transitions into a columnar or different porous structure 332 as indicated in FIG. 3. Denser means in particular that the layer 305 near the interface 331 is not porous, or in particular is less porous, in particular compared to the porous structure 332.

In FIG. 3, the following reference numbers mean:
301 Ti—Al-based substrate to be protected against oxidation.
302 Diffusion barrier layer which is applied as an intermediate layer (interface) between Ti—Al-based substrate and the oxidation barrier layer
305 Combination of oxidation barrier layer and thermal barrier layer is essentially based on the same material system (that of the oxidation barrier), but starting from the dense morphology of layer 231 from FIG. 2 in the interface to the diffusion barrier and then changing to increasingly porous morphology like layer 332 from FIG. 3, as the layer thickness increases.

FIG. 4

XRD spectrum of a Mo—Si diffusion barrier layer according to the invention, which was produced with a silane flow of 90 sccm and which detects the coexistence of Mo and MoSi2 phases in the layer.

FIG. 5

XRD spectrum of a Mo—Si diffusion barrier layer according to the invention, which was produced with a silane flow of 180 sccm and which mainly has the MoSi2 phase.

FIG. 6

SEM layer cross section of an environmental barrier coating consisting of a 4.9 μm thick Mo—Si layer (diffusion barrier) and a 2.7 μm thick Al—Cr—O layer (oxidation barrier)

FIG. 7

SEM layer cross-section of the environmental barrier layer from FIG. 6 after annealing in atmosphere at 800° C. for a period of 20 h. The Al—Cr—O layer (oxidation barrier) shows no change in thickness or morphology after annealing. In the interface to the substrate, limited diffusion takes place over an area including the diffusion barrier of a total of approx. 8 μm, which does not lead to any void formation.

FIG. 8

SEM layer cross-section of a Mo—Si diffusion barrier without the oxidation barrier. Immediately after the coating which was again carried out at 450° C., this simplified variant showed no signs of diffusion processes in the interface in the SEM layer cross section. The layer was produced with a silane flow of 180 sccm and is characterized by the XRD spectrum shown in FIG. 5.

FIG. 9

SEM layer cross-section of the Mo—Si diffusion barrier from FIG. 8 after annealing in atmosphere at 800° C. for a period of 20 h. A diffusion process occurs in the interface region in the range of approx. 2 μm. In addition, Al diffuses into the layer surface and forms an Al—O scaling.

FIG. 10

SEM layer cross-section of the Mo—Si diffusion barrier from FIG. 9, but with tenfold magnification. This makes the approximately 200 nm thick Al—O scaling more clearly visible.

### PROCESS FOR MANUFACTURING LAYER SYSTEMS

The coating process can be carried out as a combination of physical vapor deposition (PVD) and plasma-assisted chemical vapor deposition (PECVD), i.e. both methods are used, if necessary, in particular simultaneously in order to realize the layer synthesis. For example, electron beam evaporation, sputtering and/or cathodic spark evaporation can be used as PVD methods. The CVD methods are essentially based on additional gas inlets, with which the various gaseous precursors can be introduced into the coating system used. The precursors are then decomposed and excited in the plasma. Advantageously, the same coating system is used for PVD methods and for CVD methods. The plasma required for the CVD methods can be generated by means of the plasma source that is present as a result of the PVD method, i.e. for example by the cathodic spark source. However, it can also be generated in other ways, for example by a separate low-voltage arc discharge. These methods are known to those skilled in this technological field.

An example is given below which explains and describes the production of a layer system according to the invention, without this description of the exemplary layer system being intended to restrict the more general idea of the invention.

First, the process during the production of the layer system according to the invention as shown in FIG. 1 is described.

The TiAl substrates are introduced into the coating system and fixed on the appropriate holders. The holders are mounted on a substrate holder system, which is stationary during the coating process and/or can be rotated one, two and/or three times. The coating system is pumped down to a pressure of about 10⁻⁵ mbar or less. Then the substrates are pretreated. They are heated to a desired temperature (200° C. to 600° C.), in the example by means of radiant heaters, and substrate pretreatment is carried out in the system, for example cleaning of the substrate surface by sputtering with Ar gas ions. For the cleaning step, a negative voltage (substrate bias) is usually applied to the substrates. After these pre-treatment steps, in the example this negative substrate bias is set to a value, for example −40 V, which is maintained during the coating. The synthesis of a Mo—Si layer in a combination of PVD and CVD process for the diffusion barrier layer is described here as an example. The coating starts with the ignition of the cathodic spark discharge on the Mo target, which is connected as the cathode of the spark discharge and is consequently vaporized by the cathodic spark. The reactive gas is admitted at the same time or, as described for the example below, briefly offset from one another. As a supporting measure, an inert gas or an inert gas mixture can be admitted, too. In the example, the spark discharge is operated with a source current of 220 A. A silane flow of 90 sccm is added with a time delay of 2 min. A bias voltage of −40 V is applied to the substrates. In this way, the substrates are coated with a Mo—Si layer, with the chemical composition of this layer being controllable over a wide range via the evaporation rate of the Mo target (spark current) and via the silane flow. As a result, the chemical composition of the layer can be set. As an example, FIG. 4 shows an X-ray diffractogram (XRD spectrum) of such a Mo—Si layer. The characteristic Bragg peaks of this spectrum prove that under the coating parameters given above, a layer is synthesized that essentially consists of Mo and MoSi2. Matching the Mo coating rate with the silane flow allows a quasi-free choice of the existing Mo—Si compounds as described in the Mo—Si phase diagram. FIG. 5 illustrates the XRD spectrum of a Mo—Si layer that was produced with a silane flow of 180 sccm (instead of 90 sccm as in FIG. 4). In this spectrum, essentially only the Bragg peaks for the MoSi2, which was synthesized in a mixture of two crystal structures, can be seen, i.e. the higher silane flow shifts the chemical composition of the synthesized layer to the chemical compounds with the higher Si content. For certain applications, this layer can be used solely as an environmental barrier coating, namely when oxide scaling is produced on its surface. This is discussed in more detail below with reference to FIG. 8-10.

The following process step, namely the deposition of the oxidation barrier, takes place without interrupting the vacuum following the deposition of the Mo—Si layer. The transition between the deposition of the diffusion barrier and the oxidation barrier can be designed abruptly, i.e. switching off the spark discharge on the Mo target and switching off the silane flow and then starting the coating process for the oxidation barrier. However, it is also possible to choose a process transition in the coating to the oxidation barrier, in this example an Al—Cr—O layer, which is fluent and which is to be described here. For this purpose, the cathodic spark discharge is ignited on an Al—Cr target, preferably with a target composition of Al (70 at. %)-Cr (30 at %), in the last 3 minutes of the coating process for the diffusion barrier, i.e. during this process step (spark current 180 A). After a few minutes, that flow meter is also set to gas inlet, which supplies an oxygen flow of 400 sccm to the coating system. A few minutes can be understood to mean in particular about 0.5 minutes to about 15 minutes, preferably about 2 minutes to about 9 minutes, preferably about 2 minutes, preferably about 9 minutes, or in particular about 4 minutes to about 6 minutes. In a further embodiment of the invention, a few minutes can also be understood to mean other time specifications. After the oxygen flow has stabilized (approx. 1 minute), the Mo target is switched off and the silane flow meter is set to seal the silane gas inlet, i.e. the silane flow is switched off. The result is the formation of an Al—Cr—O layer on and slightly overlapping the Mo—Si diffusion barrier.

If a layer system according to the invention shown in FIG. 2 or 3 is to be produced, the next step in the process sequence is either an expansion of the oxidation barrier layer to greater thicknesses (according to FIG. 3) and with a correspondingly higher porosity (e.g. by increasing the oxygen gas flow) or a layer deposition (corresponding to FIG. 2) using the appropriate targets, such as those made of Zr—Y, around a YSZ layer as described in Table 3.

### Examples of the Layers Produced According to the Invention

A layer system comprising and/or consisting of a Mo—Si diffusion barrier and an oxidation barrier is shown as an example in FIG. 6 illustrating a layer cross section recorded in the scanning electron microscope (SEM), which corresponds to the layer system according to the invention of FIG. 1. The layer system consists of a 4.9 μm thick Mo—Si layer (diffusion barrier) and a 2.7 μm thick Al—Cr—O layer (oxidation barrier). FIG. 6 illustrates a layer structure that satisfies the requirements set forth above for an environmental barrier layer for the Ti—Al substrate material. The diffusion barrier prevents the diffusion of Ti into the deposited layer and the diffusion of elements of the applied layer into the substrate material. According to the process description, this method also offers the possibility of producing a Me-Si layer graded in its composition by adjusting the coating rates in the interface to the substrate. This Me-Si layer has an advantageous effect on layer adhesion. In this context, it should also be mentioned that in addition to and before the Me-Si layer, another metallic layer can be applied to the substrate as an adhesive layer to further improve the adhesion of the layer system. For example, this can be the metal from the Me-Si layer, or an adhesive layer metal can be used and a gradient to a Me layer and/or a Me-Si layer can be created.

The second requirement for an environmental barrier coating is also met with such a layer system. The Al—Cr—O layer prevents the penetration of oxygen and thus its diffusion to the interface between the substrate and the layer system.

The necessary conditions formulated to realize an environmental barrier coating on Ti—Al substrates are met by the above example. Si prevents diffusion in the interface to the substrate material during the coating. This applies to a pure Si layer, but also to Me-Si layers which guarantee better adhesion to the Ti—Al substrate and are mechanically much more stable than a pure ceramic-like Si layer. FIG. 7 shows the SEM layer cross-section of the layer system from FIG. 6, which was deposited at a substrate temperature of 450° C., after an annealing test for 20 h at 800° C. in an ambient atmosphere. The comparison of the two layer systems shows the excellent stability of the Al—Cr—O oxidation barrier, in which no changes are visible and which remains stable. The Mo—Si diffusion barrier, however, is subject to a diffusion process in the interface to the Ti—Al substrate, which, however, does not lead to void formation and destabilization of the interface.

A simplified variant of the environmental barrier coating described in FIG. 1 was also examined. This consisted in the fact that the coating of the Ti—Al substrate was terminated after the Mo—Si diffusion barrier had been deposited, i.e. the deposition of the oxidation barrier was dispensed with. Immediately after the coating, which was again carried out at 450° C., this simplified variant showed, both in the SEM cross-section and in the line scan, no signs of diffusion processes in the interface (FIG. 8) and a very abrupt transition in the layer morphology between substrate and Mo—Si diffusion barrier. The coated Ti—Al substrate was then annealed for 20 hours at 800° C. in ambient atmosphere. It was shown (this was determined by means of EDX measurements over the layer cross section) that diffusion occurred in a limited area in the interface, as a result of which an enrichment of Al took place directly towards the substrate and then an area of Ti—Si formed before the transition to Mo—Si took place. In this case, too, the diffusion or rearrangement processes in the interface to the substrate did not lead to the formation of any voids, but the layer remained stable even after annealing, as the SEM layer cross-section in FIG. 9 shows. What is particularly important, however, is that the rearrangement in the interface led to an additional diffusion of Al to the layer surface and, as a result of this diffusion and the annealing process, an oxide scaling (FIG. 10) formed on the Mo—Si layer surface. This oxide scaling is sufficient as a protective layer for many applications. In addition, it is also advantageous, if a layer system as shown in FIG. 2 or 3 is desired and the environmental barrier coating from FIG. 1 is coated with a thermal barrier layer which does not have very good properties as an oxidation barrier, such as Al—Cr—O, but allows little oxygen diffusion (as it would be in the case of YSZ). The process of the diffusion of Al to the silicide surface described above thus forms an Al—O barrier layer and stops any oxygen diffusion through the thermal barrier layer at the Al—O barrier layer, which acts as an oxidation barrier.

This process of oxide scaling is also significant in another context, namely if the transition from the Me-Si diffusion barrier layer to the oxidation barrier layer is problematic in the sense that the use of an oxygen plasma for depositing the oxidic oxidation barrier layer affects the diffusion barrier layer. In such a case, it is possible that Al—O scaling can be achieved without interrupting the vacuum by exposing the surface of the Me-Si diffusion barrier layer to non-plasma activated oxygen at elevated temperature.

The inventors tested a number of layer materials for the diffusion barrier properties for Ti—Al material and found that Me-Si layer materials are suitable for such a diffusion barrier. The selection of the specific Me-Si compounds must be made on the basis of the specific substrate materials and operating conditions and depends, for example, on the operating temperature and the choice of the oxidation barrier, which in turn depends on the corrosion conditions in the area of application. Corrosion resistance must be mentioned here as an important property of Me-Si. Me-Si layers on low alloy steel were examined in the salt spray test according to the standard ASTM B117. It turned out that these layers were stable for more than 1000 h and no corrosion occurred.

Table 1 lists many of these Me-Si compounds. According to the invention, these form a good diffusion barrier to the Ti—Al material and allow a further coating with an oxidation barrier layer in order to realize an environmental barrier coating according to FIG. 1. Table 2 lists some PVD oxide layers that are particularly suitable as an oxidation barrier layer in combination with the Me-Si compounds mentioned. All include, in addition to O, Al as an essential element. Table 3 also lists the preferred layer materials for thermal barrier layers. These include oxide layer materials with a thermal conductivity of less than 5 W/(m×K), consist of Al-, Y- and Zr-based oxides and can be produced both as a dense layer and as a porous layer with a columnar structure by changing the coating parameters.

FIG. 3 shows the combination of the environmental barrier coating from FIG. 1 with a significantly thicker oxidation barrier layer. In this layer system, the oxidation barrier layer, in addition to its actual function, also assumes the function of the thermal barrier layer due to its greater thickness. A temperature drop is achieved via this thicker oxide layer, which reduces the thermal load on the Ti—Al material and thus makes it suitable for higher operating temperatures. In principle, the oxidation barrier layer can be used as the starting material for this thermal barrier layer and can be further coated in this material system, with greater porosity being introduced into the layer by modifying the coating parameters (e.g. by increasing the oxygen flow) in order to reduce thermal conductivity. This is a preferred approach because it is simpler and more economical than coating the oxidation barrier layer with a material different from that of the oxidation barrier, such as a Zr oxide-based material that is yttria stabilized, as shown in FIG. 2.

### Description of the Tests

The tests which were made here by way of example on the layers according to the invention were carried out at 800° C. in an ambient atmosphere, respectively for 20 h and 100 h. Ti50Al50 cast material was used as a demonstration substrate for the results presented here, which are not intended to be limiting. These materials contained no dopants to make them more sensitive to diffusion processes. An essential feature of an effective environmental barrier coating system is the prevention of Ti diffusion to the surface of the layer system after the annealing process in the atmosphere, with simultaneous evidence of good adhesion between the layer system and the substrate.

### Tables

TABLE 1
Coating of the diffusion barrier according
to the invention according to FIG. 1
Layer sequence:
( . . . ) optional layers

| metallic | | Me—Si | transition |
|---|---|---|---|
| adhesive layer | gradient layer | layer | oxidation barrier |
| (Cr, Ni, Ti, Al, | (Mo/Mo—Si) | Mo—Si | (Si—O) |
| Nb, Zr) | | | |
| (Cr, Ni, Ti, Al, | (Ti/Ti—Si) | Ti—Si | (Si—O) |
| Nb, Zr) | | | |
| (Cr, Al) | (Cr/Cr—Si) | Cr—Si | (Si—O, Cr—O) |
| (Cr, Ni, Ti, Al) | (Ni/Ni—Si) | Ni—Si | (Si—O) |
| (Cr, Ti, Al) | (Al/Al—Si) | Al—Si | (Si—O, Al—O) |
| (Cr, Ti, Al, Zr) | (Zr/Zr—Si) | Zr—Si | (Si—O, Zr—O) |
| (Cr, Al, Nb) | (Nb/Nb—Si) | Nb—Si | (Si—O, Nb—O) |
| (Cr, Ti, Al, Hf) | (Hf/Hf—Si) | Hf—Si | (Si—O, Hf—O) |
| (Cr, Al, Zr) | (Al—Zr—Y/ | Y—Si | (Si—O, Y—O) |
| | Y—Si) | | |
| (Cr, Ti, Al, Ta) | (Ta/Ta—Si) | Ta—Si | (Si—O, Ta—O) |
| (Cr, Ti, Al, W) | (W/W—Si) | W—Si | (Si—O) |

TABLE 2
Oxidation barrier layers according to the invention for the
various Me—Si diffusion barrier layers according to FIG. 1

| | transition | |
|---|---|---|
| Me—Si | oxidation barrier | oxidation barrier layers |
| layer | optional layers | comma is to be understood as «and/or» |
| Mo—Si | (Si—O) | Si—O, Al—O, Al—Cr—O, Cr—O |
| Ti—Si | (Si—O) | Si—O, Al—O, Al—Cr—O, Cr—O |
| Cr—Si | (Si—O, Cr—O) | Si—O, Al—O, Al—Cr—O, Cr—O |
| Ni—Si | (Si—O) | Si—O, Al—O, Al—Cr—O, Cr—O |
| Al—Si | (Si—O, Al—O) | Al—O, Al—Cr—O |
| Zr—Si | (Si—O, Zr—O) | Si—O, Al—O, Al—Cr—O |
| Nb—Si | (Si—O, Nb—O) | Si—O, Al—O, Al—Cr—O |
| Hf—Si | (Si—O, Hf—O) | Si—O, Al—O, Al—Cr—O, Hf—O, |
| | | Al—Hf—O |
| Y—Si | (Si—O, Y—O) | Al—O, Al—Cr—O, Al—Y—O, Y—O |
| Ta—Si | (Si—O, Ta—O) | Al—O, Al—Cr—O, Al—Ta—O, Ta—O |
| W—Si | (Si—O) | Si—O, Al—O, Al—Cr—O |

TABLE 3
Thermal barrier layers according to the
invention for the various oxidation barrier layers

| | oxidation barrier layers | thermal barrier layer |
|---|---|---|
| Me—Si | comma is to be understood | comma is to be |
| layer | as «and/or» | understood as «and/or» |
| Mo—Si | Si—O, Al—O, Al—Cr—O, Cr—O | Al—Cr—O, YSZ |
| Ti—Si | Si—O, Al—O, Al—Cr—O, Cr—O | Al—Cr—O, YSZ |
| Cr—Si | Si—O, Al—O, Al—Cr—O, Cr—O | Al—Cr—O, YSZ |
| Ni—Si | Si—O, Al—O, Al—Cr—O, Cr—O | Al—Cr—O, YSZ |
| Al—Si | Al—O, Al—Cr—O | Al—Cr—O, YSZ |
| Zr—Si | Si—O, Al—O, Al—Cr—O | Al—Cr—O, YSZ |
| Nb—Si | Si—O, Al—O, Al—Cr—O | Al—Cr—O, YSZ |
| Hf—Si | Si—O, Al—O, Al—Cr—O, Hf—O, | Al—Cr—O, YSZ, |
| | Al—Hf—O | Hf—O, Al—Hf—O |
| Y—Si | Al—O, Al—Cr—O, Al—Y—O, | Al—Cr—O, YSZ |
| | Y—O | |
| Ta—Si | Al—O, Al—Cr—O, Al—Ta—O, | Al—Cr—O, YSZ |
| | Ta—O | |
| W—Si | Si—O, Al—O, Al—Cr—O | Al—Cr—O, YSZ |

A surface coating for the protection of substrates with Ti—Al material has been disclosed, wherein the coating comprises a layer sequence with at least one layer, preferably according to one or more of the layer sequences given in table 2 in rows, and wherein the coating comprises an oxidation barrier which is adjusted to the diffusion barrier and preferably adjusted according to table 3, wherein the surface coating comprises a thermal barrier which is preferably adjusted to the oxidation barrier according to table 4.

A method for producing a surface coating has been disclosed, wherein the coating is applied by means of the PVD method and by means of the CVD method and the coating is preferably carried out in just one coating system.

Regardless of the claims, protection is also claimed for a surface coating for protecting substrates with Ti—Al material preferably comprising one or more of the materials from table 1, wherein the coating comprises a layer sequence with at least one layer which forms a diffusion barrier for Ti, preferably according to one or more of the layer sequences specified in table 1 in rows and wherein the coating comprises an oxidation barrier which is adjusted to the diffusion barrier and preferably adjusted according to table 2, wherein the surface coating comprises a thermal barrier which is preferably adjusted to the oxidation barrier according to table 3.

Regardless of the claims, protection is also claimed for a method for producing a surface coating according to the previous paragraph, characterized in that the coating is applied by means of the PVD method and by means of the CVD method and the coating is preferably carried out in just one coating system.

Within the scope of this disclosure, the layer system and the surface coating can—but do not have to—be used synonymously, i.e. they are in particular the same thing.

1. A surface coating for protecting substrates with Ti—Al material, comprising:
one or more of the materials from Table 1,
wherein the coating comprises a layer sequence with at least one layer which forms a diffusion barrier for Ti,
and wherein the coating comprises an oxidation barrier adjusted to the diffusion barrier,
and wherein the surface coating comprises a thermal barrier.

2. The surface coating according to claim 1, wherein the diffusion barrier is arranged between the oxidation barrier and the substrate.

3. The surface coating according to claim 1, wherein the thermal barrier is arranged directly on the oxidation barrier.

4. The surface coating according to claim 1, wherein the oxidation barrier and the thermal barrier are combined in one layer.

5. The surface coating according to claim 4, wherein the one layer is graded in the layer morphology, with the one layer in the vicinity of the substrate having a highest density of the one layer, and transitioning gradually and/or continuously into a columnar or different porous structure with increasing distance from the substrate.

6. The surface coating according to claim 1, wherein a metallic layer is deposited between the substrate and the diffusion barrier, directly on the substrate.

7. The surface coating according to claim 6, wherein the diffusion barrier is deposited on a gradient layer, and the gradient layer is deposited on the metallic layer.

8. The surface coating according to claim 1, wherein the diffusion barrier comprises at least one of the group consisting of Mo—Si, Ti—Si, Cr—Si, Ni—Si, Al—Si, Zr—Si, Nb—Si, Hf—Si, Y—Si, Ta—Si, and W—Si.

9. The surface coating according to claim 1, wherein the oxidation barrier comprises Si—O and/or Al—O and/or Al—Cr—O.

10. The surface coating according to claim 1, wherein the thermal barrier comprises Al—Cr—O and/or YSZ.

11. The surface coating according to claim 6, wherein the metallic layer comprises Cr and/or Al.

12. The surface coating according to claim 7, wherein the gradient layer is adapted to the diffusion barrier.

13. The surface coating according to claim 1, wherein a transition layer, in comprising oxide scaling, is arranged between the oxidation barrier and the diffusion barrier.

14. The surface coating according to claim 13, wherein the transition layer comprises Si—O.

15. A method for producing the surface coating according to claim 1, comprising applying the coating using a PVD method and a CVD method, and wherein the coating is preferably carried out in only one coating system.

16. The surface coating according to claim 1, wherein the coating comprises the layer sequence with at least one layer which forms the diffusion barrier for Ti according to one or more of the layer sequences specified in rows in Table 1.

17. The surface coating according to claim 1, wherein the oxidation barrier is adjusted to the diffusion barrier, which is adapted in accordance with Table 2.

18. The surface coating according to claim 1, wherein the thermal barrier is adjusted to the oxidation barrier according to Table 3.
